(19) United States
(12) Patent Application Publication
(10) Pub. No.: US 2016/0247816 A1
(43) Pub. Date: Aug. 25, 2016

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Takuji KUNIYA, Yokkaichi (JP)

(73) Assignee: Kabushiki Kaisha Toshiba, Minato-ku (JP)

(21) Appl. No.: 14/741,604

(22) Filed: Jun. 17, 2015

Related U.S. Application Data
(60) Provisional application No. 62/120,632, filed on Feb. 25, 2015.

(51) Int. Cl. H01L 27/115; H01L 21/306; H01L 21/28; H01L 23/528

(52) U.S. Cl. CPC H01L 27/11582; H01L 23/528; H01L 21/30604; H01L 21/28282

(57) ABSTRACT

According to one embodiment, a semiconductor device includes a semiconductor layer, memory cell component layers, a dividing part, and a complementary film. The memory cell component layers are provided on the semiconductor layer such that memory cells are arranged in a three-dimensional state. The dividing part extends from an upper surface of the memory cell component layers to a predetermined depth of the semiconductor layer. The dividing part includes a first spacer film made of an insulating material and provided on a side in contact with the memory cell component layers, and a filling film embedded in a region surrounded by the first spacer film. The complementary film is made of a conductive material and provided between the filling film and the semiconductor layer.

### CROSS-REFERENCE TO RELATED APPLICATIONS

This application is based upon and claims the benefit of priority from U.S. Provisional Application No. 62/120,632, filed on Feb. 25, 2015; the entire contents of which are incorporated herein by reference.

### FIELD

Embodiments described herein relate generally to a semiconductor device and a manufacturing method of a semiconductor device.

### BACKGROUND

There is known a semiconductor device designed such that structure bodies including a plurality of memory cells stacked in a height direction are arranged in a two-dimensional state on a polycrystalline silicon film. In this semiconductor device, a region including structure bodies arranged therein is partitioned by slits extending in a predetermined direction.

In a cross section perpendicular to the extending direction of the slits, the CD (Critical Dimension) at the bottom of each slit is preferably larger, and the recessed amount made by each slit into the underlying polycrystalline silicon film is preferably smaller. However, conventionally, it is difficult to achieve both these two matters together.

### BRIEF DESCRIPTION OF THE DRAWINGS

FIG. 1 is a perspective view schematically showing an example of a structure of a nonvolatile semiconductor memory device;

FIG. 2 is a top view schematically showing an example of an arrangement state in association with memory strings of a memory cell part and contacts of a word line contact part in a nonvolatile semiconductor memory device according to an embodiment;

FIG. 3 is a sectional view schematically showing an example of a configuration, which is taken in a direction perpendicular to the bit line direction, of the memory cell part in the nonvolatile semiconductor memory device according to the embodiment;

FIG. 4 is a sectional view schematically showing an example of a configuration, which is taken in a direction perpendicular to the word line direction, of the memory cell part in the nonvolatile semiconductor memory device according to the embodiment;

FIGS. 5A to 5N are sectional views schematically showing an example of a process sequence of a manufacturing method of the nonvolatile semiconductor memory device according to the embodiment.

### DETAILED DESCRIPTION

In general, according to one embodiment, a semiconductor device includes a semiconductor layer, memory cell component layers, a dividing part, and a complementary film. The memory cell component layers are provided on the semiconductor layer such that memory cells are arranged in a three-dimensional state. The dividing part extends from an upper surface of the memory cell component layers to a predetermined depth of the semiconductor layer. The dividing part includes a first spacer film made of an insulating material and provided on a side in contact with the memory cell component layers, and a filling film embedded in a region surrounded by the first spacer film. The complementary film is made of a conductive material and provided between the filling film and the semiconductor layer.

An exemplary embodiment of a semiconductor device and a manufacturing method of a semiconductor device will be explained below in detail with reference to the accompanying drawings. The present invention is not limited to the following embodiment. The sectional views, the top view, and the perspective view of a semiconductor device used in the following embodiment are schematic, and so the relationship between the thickness and width of each layer and/or the thickness ratios between respective layers may be different from actual states.

The embodiment described hereinafter is exemplified by a nonvolatile semiconductor memory device having a structure that memory cells (transistors) of the SGT (Surrounding Gate Transistor) type are provided in a height direction. Each of the memory cells includes a semiconductor film serving as a channel and formed as a vertical column above a substrate, and a gate electrode film formed on the side surface of the semiconductor film, through a tunnel insulating film, a charge accumulation film, and an inter-electrode insulating film.

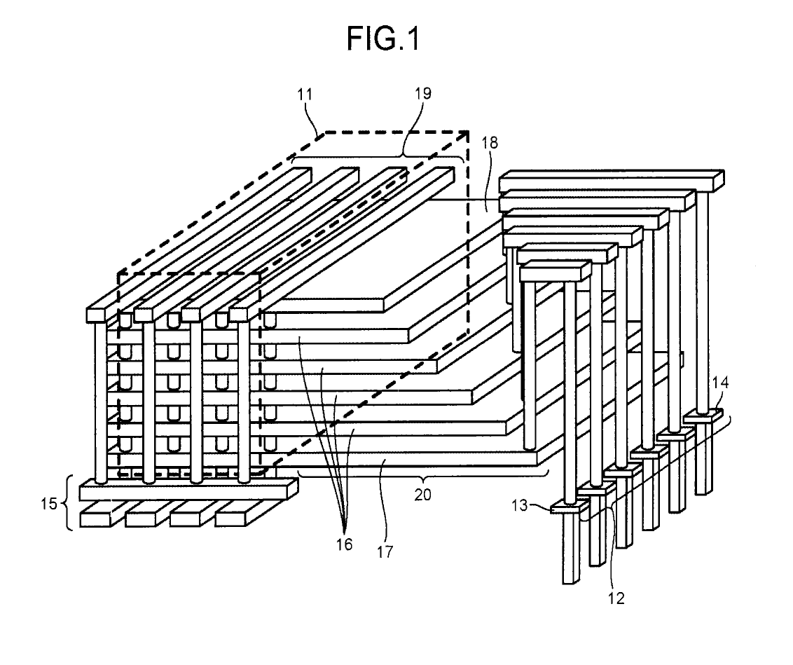

FIG. 1 is a perspective view schematically showing an example of a structure of a nonvolatile semiconductor memory device. The nonvolatile semiconductor memory device includes a memory cell part 11, a word line drive circuit 12, a source-side selection gate line drive circuit 13, a drain-side selection gate line drive circuit 14, a sense amplifier 15, word lines 16, a source-side selection gate line 17, a drain-side selection gate line 18, and bit lines 19.

The memory cell part 11 is configured such that a plurality of memory strings are arranged above a substrate, wherein each memory string includes memory cell transistors (each of which will also be simply referred to as a memory cell, hereinafter), a drain-side selection transistor and a source-side selection transistor respectively provided at the upper and lower ends of the memory cell column. As described later, each of the memory cell transistors, the drain-side selection transistor, and the source-side selection transistor is structured such that a gate electrode is formed on the side surface of a hollow columnar structure body including a semiconductor film, a tunnel insulating film, a charge accumulation film, and an inter-electrode insulating film stacked in this order. In each memory cell transistor, the gate electrode serves as a control gate electrode, and, in each of the drain-side selection transistor and the source-side selection transistor, the gate electrode serves as a selection gate electrode. The structure shown here is exemplified by a case where one memory string is provided with memory cells in four layers.

Each word line 16 connects the control gate electrodes of memory cells at the same height to each other among memory strings present within a predetermined range. The direction in which the word lines 16 extend will be referred to as a word line direction, hereinafter. Further, the source-side selection gate line 17 connects the selection gate electrodes of source-side selection transistors to each other among the memory strings present within the predetermined range, and the drain-side selection gate line 18 connects the selection gate electrodes of drain-side selection transistors to each other among the memory strings present within the predetermined range. Further, the bit lines 19 are arranged such that they are respectively connected to the upper sides of the memory strings in a direction intersecting with the word line direction (in this example, in a direction perpendicular thereto). The direction in which the bit lines 19 extend will be referred to as a bit line direction, hereinafter.

The word line drive circuit 12 is a circuit for controlling voltage to be applied to the word lines 16, the source-side selection gate line drive circuit 13 is a circuit for controlling voltage to be applied to the source-side selection gate line 17, and the drain-side selection gate line drive circuit 14 is a circuit for controlling voltage to be applied to the drain-side selection gate line 18. Further, the sense amplifier 15 is a circuit for amplifying an electric potential read from a selected memory cell. Here, in the following explanation, when there is no need to distinguish the source-side selection gate line 17 and the drain-side selection gate line 18 from each other, they will be simply referred to as selection gate lines. Further, when there is no need to distinguish the source-side selection transistor and the drain-side selection transistor from each other, they will be simply referred to as selection transistors.

The word lines 16, the source-side selection gate line 17, and the drain-side selection gate line 18 provided in the memory cell part 11 are connected to the word line drive circuit 12, the source-side selection gate line drive circuit 13, and the drain-side selection gate line drive circuit 14 respectively through contacts in a word line contact part 20 (electrode line contact part) provided for the memory cell part 11. The word line contact part 20 is arranged on a side of the memory cell part 11 facing the word line drive circuit 12, and has a structure formed such that the word lines 16 and the selection gate lines 17 and 18, which are connected to the memory cells at respective heights and the selection transistors, have been processed in a stepwise state.

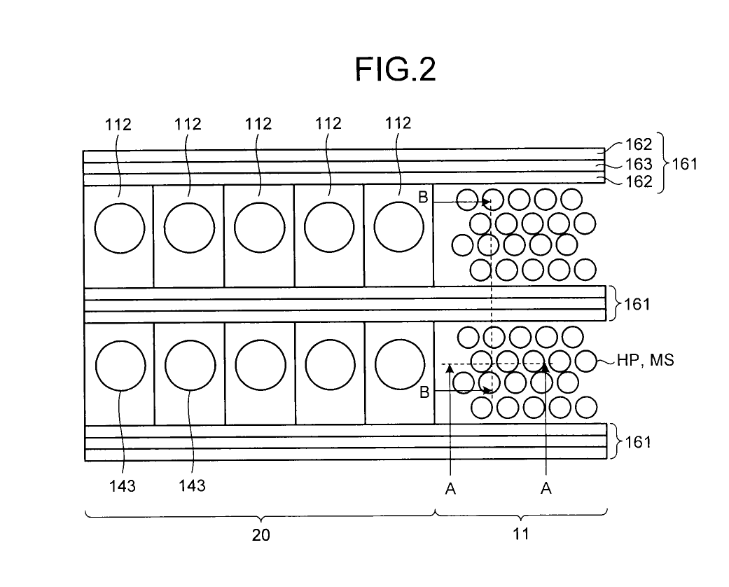

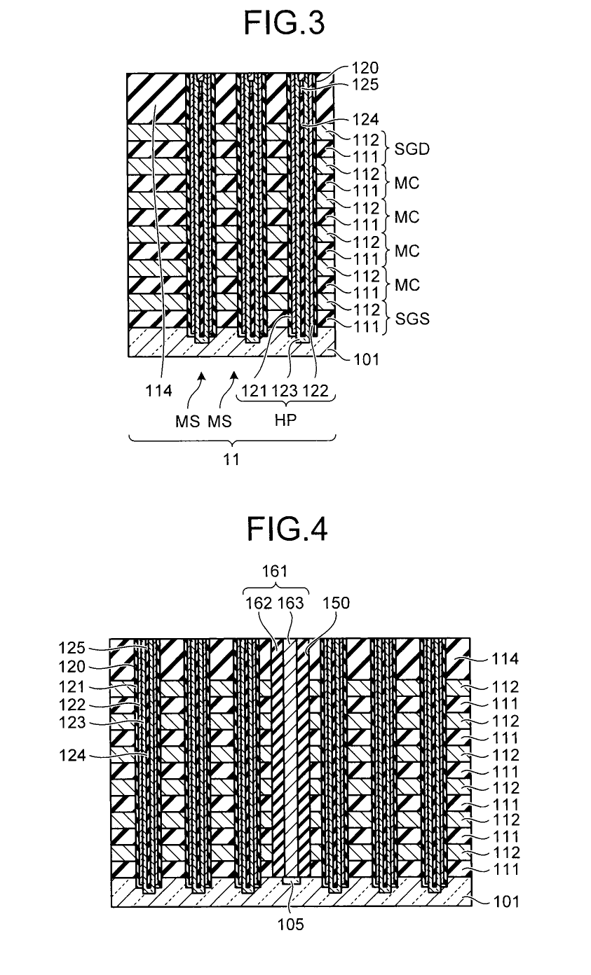

FIG. 2 is a top view schematically showing an example of an arrangement state in association with memory strings of a memory cell part and contacts of a word line contact part in a nonvolatile semiconductor memory device according to an embodiment. FIG. 3 is a sectional view schematically showing an example of a configuration, which is taken in a direction perpendicular to the bit line direction, of the memory cell part in the nonvolatile semiconductor memory device according to the embodiment. FIG. 4 is a sectional view schematically showing an example of a configuration, which is taken in a direction perpendicular to the word line direction, of the memory cell part in the nonvolatile semiconductor memory device according to the embodiment. Here, FIG. 2 is a view, seen from the top, of a portion cut by a plane parallel with the substrate surface at a position between the drain-side selection transistor and the bit lines. Further, FIG. 3 corresponds to a sectional view taken along a line A-A in FIG. 2, and FIG. 4 corresponds to a sectional view taken along a line B-B in FIG. 2.

As shown in FIGS. 2 to 4, the memory cell part 11 includes memory strings MS formed almost vertically and arranged in a two-dimensional state on a semiconductor film 101. Each memory string MS has a configuration in which a plurality of transistors are connected in series. Each memory string MS includes a pillar member HP and electrode films 112. The pillar member HP has a structure in which an ONO film 121 having a hollow columnar shape is stacked on the outer peripheral surface of semiconductor films 123 and 122 having a hollow columnar shape, wherein the ONO film 121 is composed of a tunnel insulating film, a charge accumulation film, and an inter-electrode insulating film. The hollow columnar semiconductor films 123 and 122 serve as the channels of the transistors constituting the memory string MS. Each of the semiconductor films 123 and 122 may be formed of a P-type amorphous silicon film. A plurality of electrode films 112 are arranged with spacer films 111 respectively interposed therebetween in the height direction of the pillar member HP.

Here, a filler insulating film 124, such as a silicon oxide film, is embedded in the hollow columnar semiconductor film 123 up to a predetermined height, and a cap film 125, such as a P-type amorphous silicon film, is further embedded thereon from the predetermined height.

In the column of the transistors connected in series in the height direction, the transistors at the upper and lower ends serve as selection transistors SGS and SGD. In the example shown in FIGS. 3 and 4, the source-side selection transistor SGS is arranged on the lower side, and the drain-side selection transistor SGD is arranged on the upper side. Between these two selection transistors SGS and SGD, one or more memory cell transistors MC are arranged at predetermined intervals. In this example, each of the selection transistors SGS and SGD has the same structure as the structure of each memory cell transistor MC.

As shown in FIG. 2, the memory cell part 11 and the word line contact part 20 are partitioned into a plurality of regions by dividing parts 161 that extend in the word line direction. Here, as shown in FIG. 4, each dividing part 161 has a configuration in which a spacer film 162, such as a silicon oxide film, and a filling film 163 are embedded in a slit 150 that penetrates, in the thickness direction, the stacked body formed by stacking the spacer film 111 and the electrode film 112 each in a plurality of layers. The filling film 163 may be formed of a conductive film or insulating film. If the filling film 163 is to be used as a contact for connection to an element (not shown) arranged below the memory cell part 11, the filling film 163 is formed of a conductive film, such as tungsten (W). On the other hand, if the filling film 163 is not to be used as a contact, the filling film 163 is formed of an insulating film, such as a silicon oxide film or silicon nitride film.

A complementary film 105 is provided at the bottom of each slit 150. The complementary film 105 is formed in a region including a recessed portion of the underlying semiconductor film 101 at the bottom of each slit 150. The complementary film 105 may be made of amorphous silicon, polycrystalline silicon, titanium (Ti), or tungsten. Further, the thickness of the complementary film 105 is set to be about a recessed amount of the underlying semiconductor film 101, such as 50 nm or less. The complementary film 105 serves to lower the resistance of the semiconductor film 101, which receives over-etching and thereby increases its resistance when the slit 150 is formed as described later. Further, since the complementary film 105 has no damage remaining on its upper surface due to etching as described later, if the filling film 163 is formed of a conductive film, the contact resistance between the complementary film 105 and the filling film 163 is reduced.

Here, in a case where the complementary film 105 and the filling film 163 are made of tungsten, the diameter of particles forming the complementary film 105 is smaller than the diameter of particles forming the filling film 163. For example, if each slit 150 has a width of about 160 nm in a cross section perpendicular to its extending direction, and the complementary film 105 has a thickness of 50 nm, the particles forming the complementary film 105 are smaller than the particles forming the filling film 163 that is formed in the slit 150 having a larger width. Consequently, by comparing the size of the particles forming the complementary film 105 with that of the filling film 163, the interface between these films can be estimated.

The transistors at the same height in each region present between dividing parts 161 are connected to each other by the same electrode film 112. For example, the source-side selection transistors SGS in each region present between dividing parts 161 are connected to each other by the lowermost layer electrode film 112. The drain-side selection transistors SGD in each region present between dividing parts 161 are connected to each other by the uppermost layer electrode film 112. These electrode films 112 serve as selection gate lines.

As shown in FIG. 2, the word line contact part 20 is provided with word line contacts 143 respectively connected to the electrode films 112. The lower ends of the word line contacts 143 are respectively connected to the electrode films 112, which serve as the word lines 16 and the selection gate lines 17 and 18 and are arranged in a stepwise state, as shown in FIG. 1.

Further, the memory cells MC at the same height in each region present between dividing parts 161 are connected to each other by the corresponding one of the electrode films 112. Each electrode film 112 connecting the memory cells MC serves as a word line.

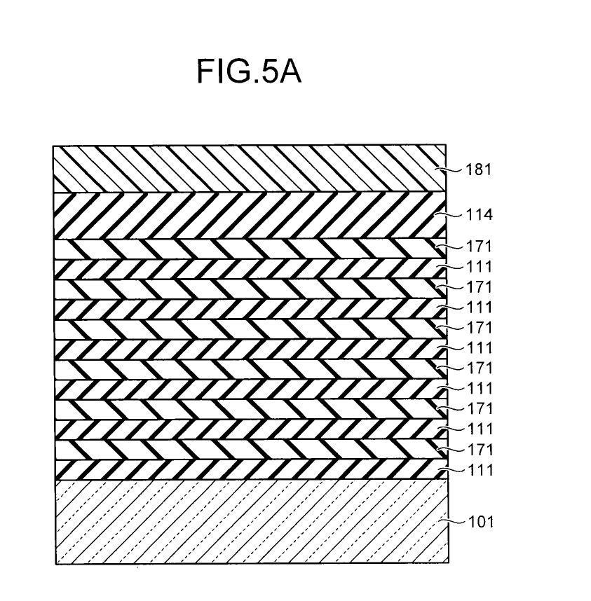

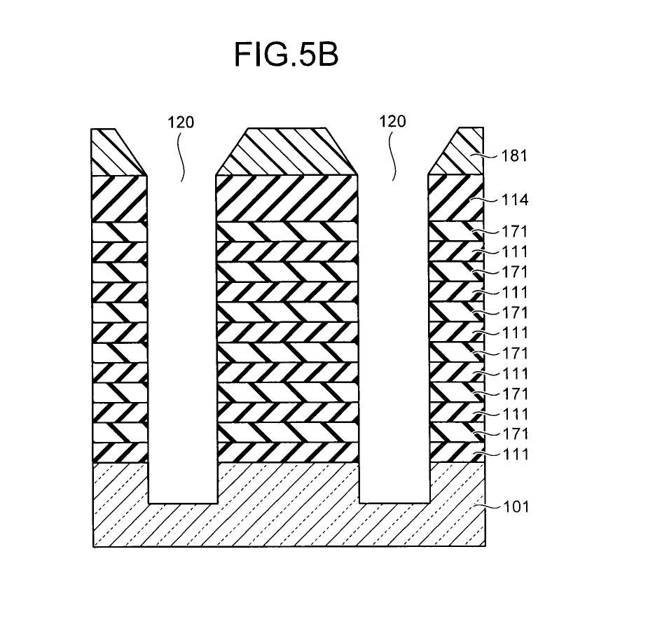

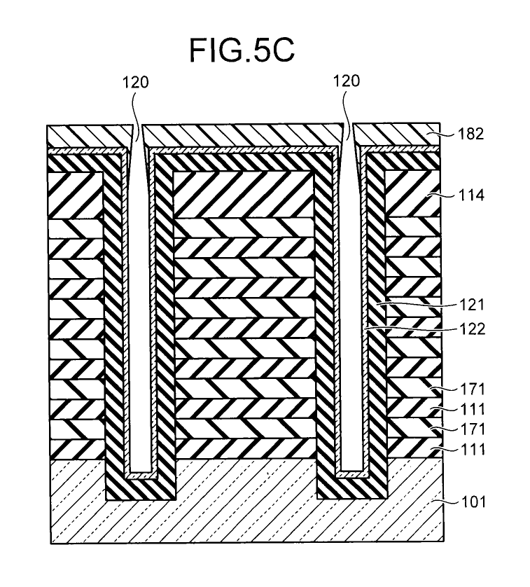

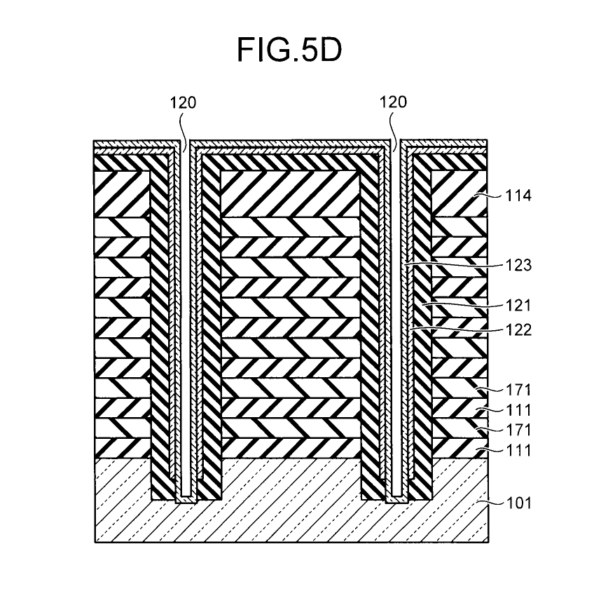

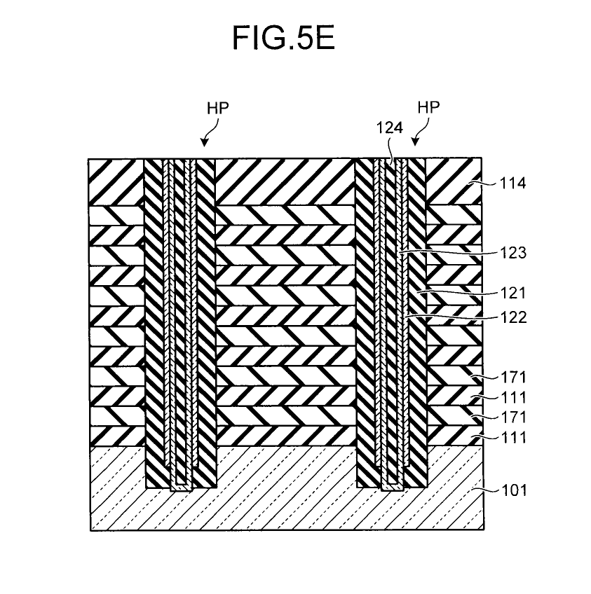

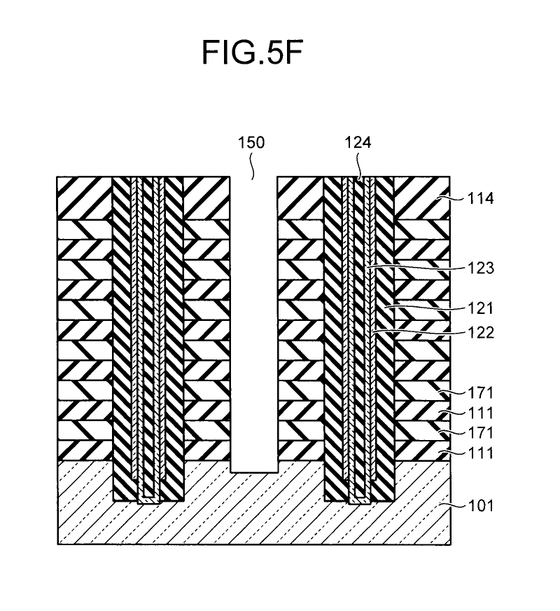

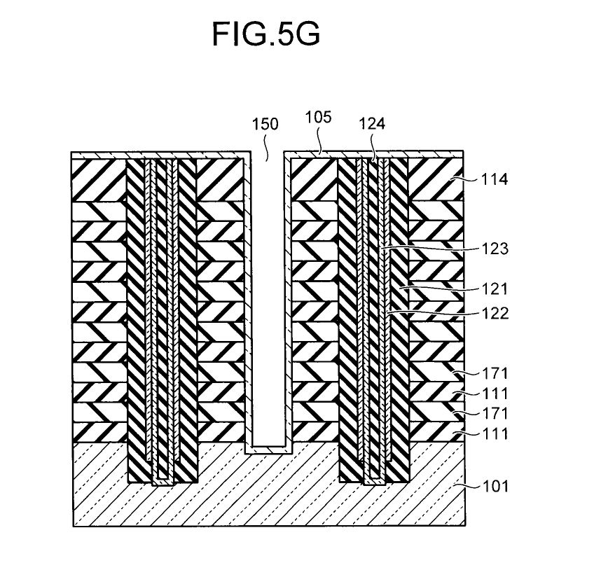

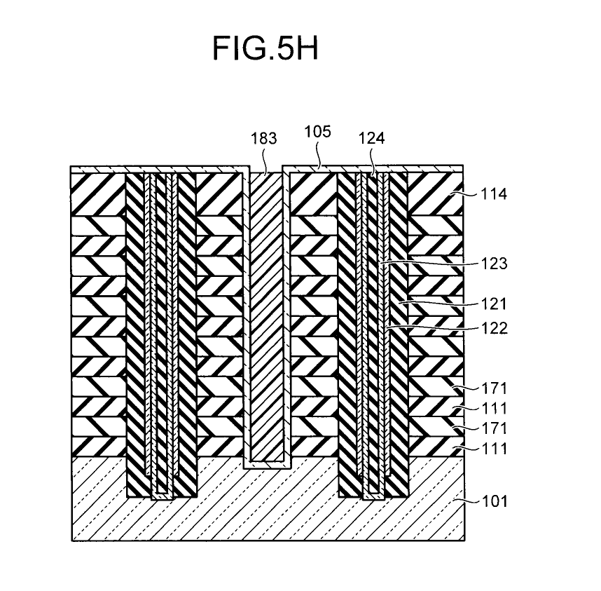

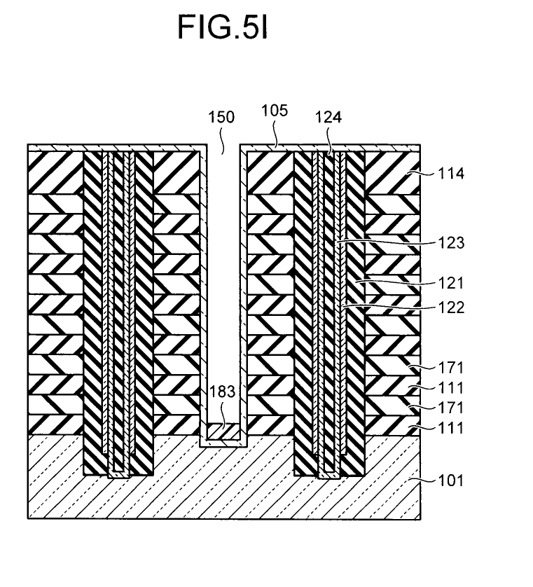

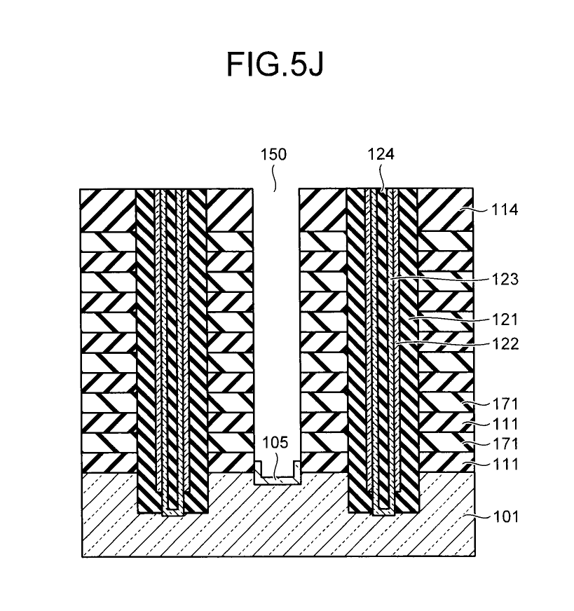

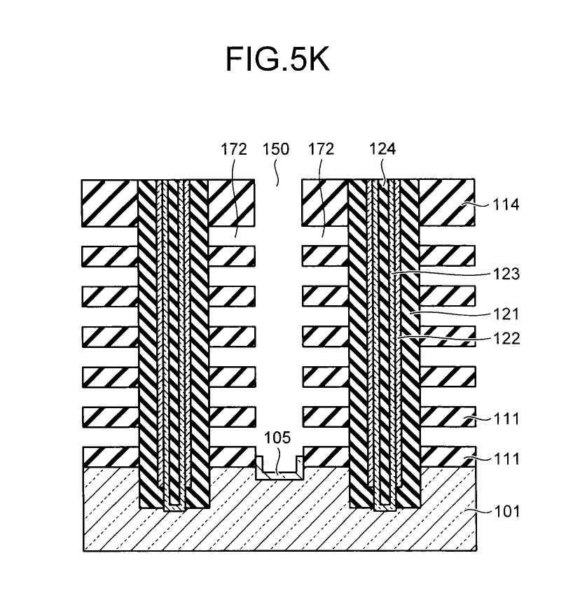

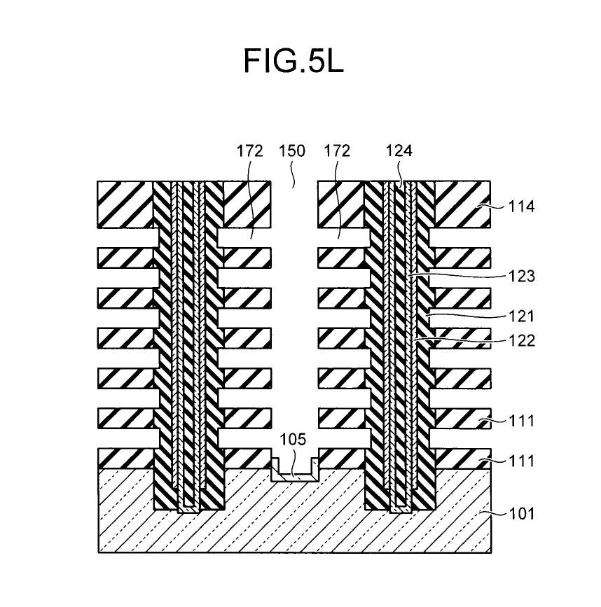

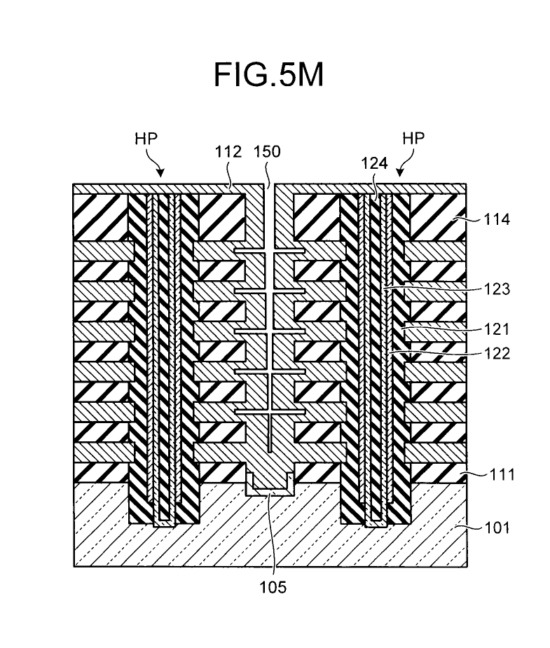

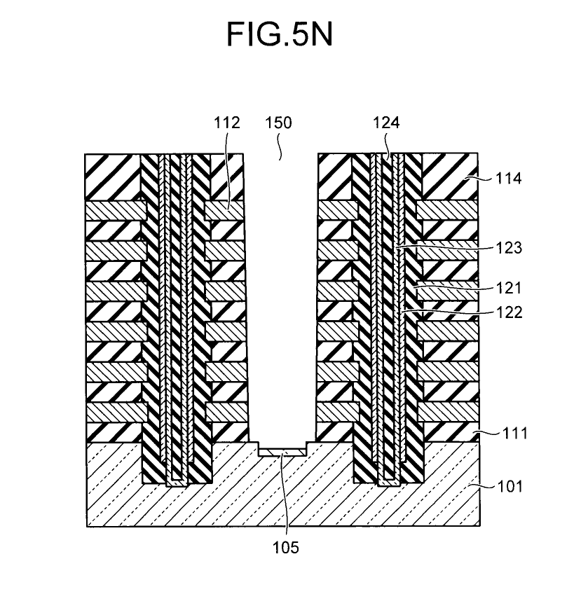

Next, an explanation will be given of a manufacturing method of the nonvolatile semiconductor memory device having this configuration. FIGS. 5A to 5N are sectional views schematically showing an example of a process sequence of a manufacturing method of the nonvolatile semiconductor memory device according to the embodiment. Here, FIGS. 5A to 5N correspond to part of the sectional view taken along the line B-B in FIG. 2.

At first, peripheral circuit elements and so forth are formed on a semiconductor substrate, such as a silicon substrate, (not shown). An interlayer insulating film is formed on the semiconductor substrate thus provided with the peripheral circuit elements and so forth, and is planarized. Then, as shown in FIG. 5A, a semiconductor film 101 is formed on the interlayer insulating film. The semiconductor film 101 is made of polycrystalline silicon, for example. Further, a spacer film 111 and a sacrificial film 171 are alternately stacked each in a predetermined number of layers on the semiconductor film 101, and an insulating film 114 is further stacked as the uppermost portion, so that a stacked body is formed. Further, a resist 181 is applied onto the entire surface of the stacked body.

The spacer film 111 may be formed of a silicon oxide film, for example. The insulating film 114 may be made of the same material as that of the spacer film 111, and may be formed of a silicon oxide film, for example. The sacrificial film 171 may be formed of a silicon nitride film, for example. The thickness of each of the spacer film 111 and the sacrificial film 171 may be set to several ten nm.

Then, as shown in FIG. 5B, patterning is performed to the resist 181 by use of a lithography technique and a development technique. Here, the pattern is formed to include openings at positions for forming memory strings MS. Then, anisotropic etching is performed by use of an RIE (Reactive Ion Etching) method or the like, through the resist 181 serving as a mask, so that memory holes 120 are formed. The memory holes 120 are formed to penetrate the stacked body in the thickness direction. Further, the bottom of each memory hole 120 reaches the semiconductor film 101.

Thereafter, as shown in FIG. 5C, an ONO film 121, which is formed of stacked films of a silicon oxide film/a silicon nitride film/a silicon oxide film, is formed to cover the upper surface of the insulating film 114 and the inner surfaces of the memory holes 120. The ONO film 121 provides the functions of an inter-electrode insulating film, a charge accumulation film, and a tunnel insulating film, from the side adjacent to the inner surface of each memory hole 120. The thickness of the ONO film 121 may be set to 15 nm, for example.

Then, a semiconductor film 122 is formed on the ONO film 121. The semiconductor film 122 is formed such that it covers, also in a conformal state, each memory hole 120 including the ONO film 121 formed thereon. This semiconductor film 122 serves to cover and prevent part of the ONO film 121 formed on the sidewall of each memory hole 120 from being removed, when part of the ONO film 121 formed at the bottom of each memory hole 120 is being removed by etching. The semiconductor film 122 may be made of amorphous silicon. Further, its thickness may be set to 7 nm. Further, a resist 182 is applied onto the entire surface of the semiconductor film 122, and is subjected to patterning by use of a lithography technique and a development technique, so that openings are formed at positions corresponding to the memory holes 120.

Thereafter, anisotropic etching is performed by use of an RIE method or the like, through the resist 182 serving as a mask, so that part of the semiconductor film 122 and part of the ONO film 121 at the bottom of each memory hole 120 are removed. Then, the resist pattern is removed, and, thereafter, as shown in FIG. 5D, a semiconductor film 123 is formed to cover the upper surface of the semiconductor film 122 and the inner surfaces of the memory holes 120. The semiconductor film 123 may be made of amorphous silicon. Further, its thickness may be set to 15 nm. The semiconductor films 122 and 123 are used to serve as the channels of the memory cells MC and the selection transistors SGS and SGD. Further, the semiconductor films 122 and 123 and the ONO film 121 respectively have hollow and circular columnar shapes and they form a stacked structure in the radial direction.

Then, as shown in FIG. 5E, a filler insulating film 124 is formed on the upper surface of the semiconductor film 123 and is embedded in each memory hole 120 covered with the ONO film 121 and the semiconductor films 122 and 123. Thereafter, the films existing above the insulating film 114 are removed by use of a CMP (Chemical Mechanical Polishing) method, so that the upper surface is planarized. Consequently, a hollow columnar pillar member HP including the ONO film 121 and the semiconductor films 122 and 123 is formed inside each memory hole 120.

Thereafter, as shown in FIG. 5F, a resist (not shown) is applied onto the stacked body, and then a resist pattern including openings for forming slits is formed by use of a lithography technique and a development technique. The openings for forming slits have shapes extending in the word line direction, and they are formed at predetermined intervals in the bit line direction over an area including the memory cell part 11 and the word line contact part 20.

Then, anisotropic etching is performed by use of an RIE method or the like to etch the stacked body, through the resist pattern (not shown) serving as a mask, so that slits 150 are formed. Each slit 150 reaches the semiconductor film 101. In general, a fluorocarbon based gas is used for etching an insulating film including an oxide film, but, in this embodiment, the etching is performed under conditions (which will be referred to as non-deposit conditions, hereinafter) to prevent deposition products of the etching from being deposited on the side surface of each slit 150. For example, the deposition products of the etching are formed by deposition of components derived from an etching gas due to decomposition or combination in plasma, or deposition of etching by-product generated by the etching. In the case of a fluorocarbon based gas, the non-deposit conditions are conditions for using an etching gas having a small C/F ratio, such as CF₄.

When the etching is performed to the stacked body under the non-deposit conditions, the amount of deposition products deposited on the sidewall of each slit 150 during the etching is reduced. In this case, the stacked body comes to have a taper angle of almost a right angle in a cross section perpendicular to the extending direction of each slit 150 thus formed. As a result, the width (CD) at the bottom can be set to a desired value without increasing the width at the top.

Further, the amount of carbon (C) implanted into the underlying semiconductor film 101 (silicon film) at the bottom of each slit 150 can be reduced. If carbon is implanted into the semiconductor film 101, the resistance of the semiconductor film 101 is deteriorated due to generation of damage and diffusion of carbon. On the other hand, in this embodiment, since the etching is performed under the non-deposit conditions, the resistance of the semiconductor film 101 is suppressed from being deteriorated.

However, when the etching is performed under the non-deposit conditions, it is difficult to attain a selective ratio relative to the underlying semiconductor film 101 (silicon film). Consequently, the semiconductor film 101 is dug down and the thickness of the semiconductor film 101 is reduced at the position where each slit 150 is formed, and the resistance thereby ends up being increased if it remains in this state.

Accordingly, in this embodiment, as shown in FIG. 5G, a complementary film 105 formed of a conductive film is provided on the stacked body to complement that part of the underlying semiconductor film 101, which has been dug down when the slits 150 are formed by the etching. The complementary film 105 is formed to cover the inner surface of each slit 150 in a conformal state. The complementary film 105 may be made of a material that is isotropically etched when the complementary film 105 is etched later. A material of this kind may be exemplified by amorphous silicon, polycrystalline silicon, tungsten, or titanium, for example. Further, the thickness of the complementary film 105 may be set to a value, for example, in accordance with the width of each slit 150 and an estimated dug amount of the underlying semiconductor film 101. For example, the complementary film 105 is set to have a thickness almost equal to the estimated dug amount of the semiconductor film 101.

Then, as shown in FIG. 5H, a resist 183 is applied onto the stacked body, and processed by use of a lithography technique and a development technique, so that the resist 183 is embedded only in the slits 150. Thereafter, as shown in FIG. 5I, the resist 183 inside the slits 150 is etched back by use of an oxygen based gas. For example, the resist 183 is etched back to a position around the lowermost set of a spacer film 111 and a sacrificial film 171. In other words, part of the resist 183 is left within a range of from the bottom of each slit 150 to a predetermined height.

Then, as shown in FIG. 5J, anisotropic etching is performed by use of an RIE method or the like, so that the complementary film 105 is etched back. During this etching, the material, such as amorphous silicon, polycrystalline silicon, tungsten, or titanium, tends to provide chemical etching relative to an insulating film, such as an oxide film. Thus, part of the complementary film 105 formed on the sidewall of each slit 150 is removed even by the anisotropic etching. Consequently, part of the complementary film 105 is left at a region where the resist 183 remains, and the other part of the complementary film 105 is removed at the other regions. Thereafter, the resist at the bottom of each slit 150 is removed by a resist stripping process using oxygen plasma or the like.

Then, as shown in FIG. 5K, the sacrificial films 171 are removed by etching. For example, wet etching using hot phosphoric acid, or dry etching, such as CDE (Chemical Dry Etching), is performed, so that each sacrificial film 171 formed of an SiN film is removed. More specifically, the etchant penetrates through the slits 150 formed as described above, and etches each sacrificial film 171 above the semiconductor film 101. Thus, a gap space 172 is formed at the region where each sacrificial film 171 has been present. As a result, as shown in FIG. 5K, a structure is provided such that the spacer films 111 and the insulating film 114 are supported by the side surfaces of the hollow columns, each of which stands perpendicular to the semiconductor film 101 and is formed of stacked films of the semiconductor films 123 and 122 and the ONO film 121. At this time, the etching is performed under conditions by which the selective ratio of the sacrificial films 171 relative to the spacer films 111 and the insulating film 114 is set to be sufficiently large.

Then, as shown in FIG. 5L, the ONO film 121 as partly removed by etching. For example, wet etching using dilute hydrofluoric acid is performed, so that the silicon oxide film forming the inter-electrode insulating film of the ONO film 121 is partly removed. At this time, the etching time is controlled not to entirely remove the inter-electrode insulating film.

Thereafter, as shown in FIG. 5M, an electrode film 112 is formed in a conformal state by a film formation method, such as a CVD method, in the slits 150 and the gap spaces 172 between the spacer films 111 in the vertical direction. More specifically, the electrode film 112 is formed to cover the surfaces of the spacer films 111 and the insulating film 114 protruding in the direction parallel with the substrate surface, and to cover the side surfaces of the pillar members HP in contact with the gap spaces 172. The electrode film 112 may be made of tungsten or the like.

Then, as shown in FIG. 5N, anisotropic etching is performed by use of an RIE method or the like, so that part of the electrode film 112 deposited on the side surfaces of the insulating film 114 and the spacer films 111 inside each slit 150 is removed. Further, anisotropic etching is performed by use of an RIE method or the like to the insulating film 114, the spacer films 111, and the electrode film 112, so that the side surface of each slit 150 becomes almost flat. Consequently, the width of each slit 150 becomes larger than that originally formed, as the case may be.

Then, a spacer film 162 is formed to cover the upper surface of the insulating film 114 and the inner surface of each slit 150. The spacer film 162 may be exemplified by an insulating film, such as a silicon oxide film. Thereafter, anisotropic etching is performed by use of an RIE method or the like, so that the spacer film 162 is etched back and is partly left only on the side surface of each slit 150. Thereafter, a filling film 163 is embedded in each slit 150. The filling film 163 may be formed of a conductive film or insulating film.

If the filling film 163 is to be used as a contact, it is formed of a conductive film. This conductive film may be made of tungsten or the like, for example. In this case, the conductive complementary film 105 (amorphous silicon film) is embedded near the center of the bottom of each slit 150. The complementary film 105 has no etching damage on its surface and contains no carbon, which is a component of an etching gas, diffused in its surface. Consequently, the filling film 163 formed of a conductive film and the conductive complementary film 105 come into good contact with each other, and thereby reduce the contact resistance therebetween. Further, when the conductive complementary film 105 and the filling film 163 form a good contact state, silicide is formed at the interface therebetween, and thus the resistance is lowered.

Thereafter, part of the filling film 163 above the stacked body is removed by a CMP method or the like. As a result, the nonvolatile semiconductor memory device shown in FIGS. 3 and 4 is obtained.

In the explanation described above, a NAND type flash memory having an SGT structure is taken as an example. However, other than this, this embodiment may be applied to a semiconductor device having a configuration in which memory cells of a ReRAM (Resistive Random Access Memory), MRAM (Magnetoresistive Random Access Memory), or DRAM (Dynamic Random Access Memory) are arranged in a three-dimensional state.

According to the embodiment, a semiconductor device including memory cells MC arranged in a three-dimensional state on the semiconductor film 101 is provided with the complementary film 105 in a recessed portion of the semiconductor film 101 at a position for forming each dividing part 161 that partitions a region. The complementary film 105 is formed of a conductive film, which has no etching damage on its surface and contains no carbon, which is a component of an etching gas, diffused in its surface. Consequently, it is possible to reduce the contact resistance between the complementary film 105 and the filling film 163 formed of a conductive film arranged thereon. Further, the semiconductor film 101 is recessed at the position for forming each dividing part 161 and reduces its thickness, and the resistance of the semiconductor film 101 thereby ends up being increased. However, it is possible to suppress an increase in the resistance by providing the complementary film 105 at the recessed portion.

Further, according to the embodiment, when the slits 150 are formed in the films for constituting memory cells MC arranged in a three-dimensional state (which will be referred to as memory cell component layers, hereinafter), which are provided on the semiconductor film 101, the slits 150 are formed by etching under conditions with a small C/F ratio. Consequently, it is possible to set the width of each slit 150 to be almost uniform from the top to the bottom in a cross section perpendicular to the extending direction of the slits 150, and to set the width at the bottom to a desired value. Further, when the slits 150 are formed, the recessed portion of the semiconductor film 101 below the memory cell component layers is complemented by the conductive complementary film 105. Consequently, it is possible to reduce the contact resistance between the semiconductor film 101 and the conductive filling film 163 embedded in each slit 150.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer;
memory cell component layers provided on the semiconductor layer such that memory cells are arranged in a three-dimensional state;
a dividing part extending from an upper surface of the memory cell component layers to a predetermined depth of the semiconductor layer, the dividing part including a first spacer film made of an insulating material and provided on a side in contact with the memory cell component layers, and a filling film embedded in a region surrounded by the first spacer film; and
a complementary film made of a conductive material and provided between the filling film and the semiconductor layer.

2. The semiconductor device according to claim 1, wherein
the semiconductor layer includes a recessed portion formed by a recess of a surface on which the memory cell component layers are formed, within a region where the dividing part is arranged, and
the complementary film is embedded in the recessed portion of the semiconductor layer.

3. The semiconductor device according to claim 1, wherein the complementary film is made of amorphous silicon, polycrystalline silicon, tungsten, or titanium.

4. The semiconductor device according to claim 1, wherein the filling film is made of a conductive material.

5. The semiconductor device according to claim 4, wherein the filling film is made of tungsten.

6. The semiconductor device according to claim 1, wherein
the complementary film is made of amorphous silicon or polycrystalline silicon,
the filling film is made of tungsten, and
tungsten silicide is provided at an interface between the complementary film and the filling film.

7. The semiconductor device according to claim 1, wherein the filling film is made of an insulating material.

8. The semiconductor device according to claim 1, wherein the dividing part is provided to extend in a predetermined direction.

9. The semiconductor device according to claim 8, wherein
the memory cell component layer includes memory strings which are arranged in a two-dimensional state on the semiconductor layer, each of the memory strings including a channel layer arranged perpendicular to the semiconductor layer and memory cells arranged at predetermined intervals on a side surface of the channel layer in its extending direction, and
the memory cells at a same height in a region partitioned by the dividing part are connected to a same wiring layer.

10. The semiconductor device according to claim 9, wherein
each of the memory cells includes a control gate electrode film arranged on the side surface of the channel layer in its extending direction through a tunnel insulating film, a charge accumulation film, and an inter-electrode insulating film, and
the control gate electrode films of the memory cells at the same height in the region partitioned by the dividing part are connected to each other by the wiring layer.

11. The semiconductor device according to claim 9, further comprising a second spacer film made of an insulating material, the second spacer film is arranged between layers of the wiring layer adjacent to each other in the extending direction of the channel layer.

12. A manufacturing method of a semiconductor device, the method comprising:
forming a memory cell component layer constituting memory cells on a semiconductor layer;
etching the memory cell component layer from an upper surface to a predetermined depth of the semiconductor layer to form a slit;
forming a complementary film made of a conductive material on an upper surface of the memory cell component layer and an inner surface of the slit;
embedding a resist into the slit;
etching back the resist such that an upper surface of the resist is higher than an upper surface of the semiconductor layer at the bottom of the slit;
removing part of the complementary film at a region other than a region covered with the resist;
forming a first spacer film which is made of an insulating material and covers a side surface of the slit; and
embedding a filling film into the slit covered with the first spacer film.

13. The manufacturing method of a semiconductor device according to claim 12, wherein the complementary film is made of amorphous silicon, polycrystalline silicon, tungsten, or titanium.

14. The manufacturing method of a semiconductor device according to claim 12, wherein the filling film is made of a conductive material.

15. The manufacturing method of a semiconductor device according to claim 14, wherein the filling film is made of tungsten.

16. The manufacturing method of a semiconductor device according to claim 12, wherein the filling film is made of an insulating material.

17. The manufacturing method of a semiconductor device according to claim 12, wherein in the forming the complementary film, the complementary film with a thickness almost equal to a recessed amount of the semiconductor layer made in the etching is formed.

18. The manufacturing method of a semiconductor device according to claim 12, wherein in the etching, the slit extending in a predetermined direction is formed.

19. The manufacturing method of a semiconductor device according to claim 18, wherein the forming memory cell component layers includes
alternately stacking a second spacer film and a sacrificial film each in a plurality of layers to form a stacked body, the second spacer film and the sacrificial film being respectively made of insulating materials different from each other,
forming a memory hole penetrating the stacked body in a stacked direction by etching, and
forming an inter-electrode insulating film, a charge accumulation film, a tunnel insulating film, and a channel semiconductor film, in this order, on a side surface of the memory hole.

20. The manufacturing method of a semiconductor device according to claim 19, the method further comprises:
removing, after the removing part of the complementary film and before the forming the first spacer film, each sacrificial film by etching through the slit;
embedding an electrode film into each gap space formed by removing each sacrificial film; and
etching part of each electrode film and part of each second spacer film such that a side surface of the slit becomes almost flat within a position where the slit is formed.
